(19) United States
(12) Patent Application Publication
(10) Pub. No.: US 2026/0318993 A1
(43) Pub. Date: Oct. 15, 2026

(54) MOTOR COMPONENT TESTING METHODOLOGIES INCLUDING SIMULATIONS

(71) Applicant: Carpenter Technology Corporation, Philadelphia, PA (US)

(72) Inventors: Jaydip Das, Santa Clara, CA (US); Chad Milshaw, Reading, PA (US)

(21) Appl. No.: 19/642,207

(22) Filed: Apr. 8, 2026

Related U.S. Application Data
(60) Provisional application No. 63/787,297, filed on Apr. 11, 2025.

(51) Int. Cl. G01R 31/34

(52) U.S. Cl. CPC G01R 31/34

(57) ABSTRACT

A method of determining a magnetic property of a finished motor component having a stack of mechanically coupled layers. A loose ring set of at least one loose ring with a uniform magnetic flux distribution is measured to determine a magnetic property M1. Each loose ring has a same thickness and material parameters as at least one component layer of the stack of the finished motor component. The finished motor component is fabricated and measured to determine a measured magnetic property M2 of a portion thereof. A finite element analysis simulation is performed to determine a simulated magnetic flux distribution, and a simulated magnetic property S1 of a geometry of the finished motor component is calculated. A magnetic property correction factor is derived by dividing S1 by M1. A magnetic property M3 of the finished motor component is determined by dividing M2 by the magnetic property correction factor.

### CROSS-REFERENCE TO RELATED APPLICATION

This application claims priority to U.S. Provisional Patent Application No. 63/787,297, filed on Apr. 11, 2025, the entire contents of which are incorporated herein by reference.

### BACKGROUND

Electric motors include various components, such as stators and rotors. A stator is a stationary electrical component, while a rotor is a rotating electrical component, housed within the stator, that creates a rotational force for the motor. Stators and rotors are typically fabricated by bonding multiple layers, or rings, of material into a stack.

Current processes used in determining magnetic properties of a stator or rotor, and for the rings that they are composed of, do not provide sufficiently accurate magnetic property values. At the present time, the magnetic properties of loose rings are measured after annealing/prior to bonding. Since the loose rings have a smooth profile, they do not have the same geometry as mechanically coupled component layers of a finished motor component. Thus, designers generally multiply a magnetic property value, such as core loss, of the loose rings by an arbitrary factor, such as 1.5-2, to account for the difference in geometry along with post processing procedures, such as bonding. Next, a prototype of a finished motor assembly that includes a stack, created by bonding modified rings (i.e., component layers), is measured and subsequently, based on the attained measurements, the multiplier is modified before the next prototype is created. Prototyping, testing, and further design modifications occur after this step, requiring a number of iterations to optimize the final design and processes for intended motor responses. When the final design has been determined, the loose rings are tested after annealing for production quality control. The current process does not capture the inherent variability in the production of stacks, does not help designers understand the impact for post processing for stack manufacturing such as bonding, and adds on to motor development time. In addition, the loose rings do not reflect the magnetic responses at the stack level. There is a need for a method to produce accurate stator or rotor stack data that designers can use to predict motor responses using the data to reduce motor development time and as well, track the finished stack responses at production scale.

### SUMMARY

A new process can also mitigate and optimize the post processing techniques and track the quality and magnetic health of the finished stack at production scale to aid in quality control.

In an aspect, embodiments of the invention relate to a method of determining a magnetic property of a finished motor component comprising a stack including a plurality of mechanically coupled component layers. The method includes measuring a loose ring set of at least one loose ring with a uniform magnetic flux distribution to determine a measured magnetic property M1 of the loose ring set, each loose ring having a same thickness and material parameters as at least one component layer of the stack of the finished motor component. The finished motor component is fabricated, with the finished motor component comprising the stack. The finished motor component is measured to determine a measured magnetic property M2 of a portion of the finished motor component. A finite element analysis simulation is performed to determine a simulated magnetic flux distribution of a geometry of the finished motor component. A simulated magnetic property S1 of a plurality of component layers corresponding to the mechanically coupled component layers of the finished motor component is calculated using the simulated magnetic flux distribution, with the simulated magnetic property S1 being a function of the measured magnetic property M1 of the loose ring set. A magnetic property correction factor is calculated based on a ratio of (i) the simulated magnetic property S1 of the plurality of component layers to (ii) the measured magnetic property M1 of the loose ring set. A magnetic property M3 of the finished motor component is determined by dividing the measured magnetic property M2 of the portion of the finished motor component by the magnetic property correction factor.

One or more of the following features may be included. The finished motor component may include a stator or a rotor. The magnetic property M1, M2, M3 may be at least one of magnetic flux density, magnetic field strength, and core loss.

The magnetic property M3 may be determined using at least one of (i) a plurality of flux densities and (ii) a plurality of frequencies. The magnetic property M3 may include core loss, and determining the measured magnetic property of the loose rings may include calculating the core loss.

The portion of the finished motor component may be a back iron portion, a tooth extending radially from the back iron portion, or a portion of a cylindrical body of the finished motor component.

### BRIEF DESCRIPTION OF THE DRAWINGS

FIG. 1 is a flow chart illustrating a method for determining a magnetic property of a finished motor component having a stack including a plurality of mechanically coupled component layers in accordance with an embodiment of the invention.

FIG. 2A is a perspective view of a set of loose rings in accordance with an embodiment of the invention.

FIG. 2B is a side view of a set of loose rings in accordance with an embodiment of the invention.

FIG. 3A is a top view of a finished motor component (stator) in accordance with an embodiment of the invention.

FIG. 3B is a side view of a stator having a stack including a plurality of mechanically coupled component layers in accordance with an embodiment of the invention.

FIG. 3C is a top view of a stator drawing displaying a back iron width and an effective back iron width.

FIG. 4A is a simulated geometry of a finished motor component (stator) in accordance with an embodiment of the invention.

FIG. 4B is a simulated geometry of a finished motor component (rotor) in accordance with an embodiment of the invention.

FIG. 4C is a top view of a simulated geometry of a finished motor component (rotor) in accordance with an embodiment of the invention.

FIG. 5A is a finite element analysis simulation of a back iron portion of a finished motor component containing teeth in which the tooth width to back iron width ratio is 0.54 in accordance with an embodiment of the invention.

FIG. 5B is a finite element analysis simulation of a back iron portion of a finished motor component containing teeth in which the tooth width to back iron width ratio is 0.88 in accordance with an embodiment of the invention.

FIG. 5C is a finite element analysis simulation of a back iron portion of a finished motor component containing teeth in which the tooth width to back iron width ratio is 1.54 in accordance with an embodiment of the invention.

FIG. 5D is a finite element analysis simulation of a back iron portion of a finished motor component containing teeth in which the tooth width to back iron width ratio is 1.57 in accordance with an embodiment of the invention.

FIG. 5E is a finite element analysis simulation of a back iron portion of a finished motor component containing teeth in which the tooth width to back iron width ratio is 3.16 in accordance with an embodiment of the invention.

FIG. 6 is a finite element analysis simulation of a back iron portion of a finished motor component containing a notch in accordance with an embodiment of the invention.

FIG. 7A is a comparison of finite element analysis simulations of a back iron portion of a finished motor component, the first back iron portion including no notch and the second back iron portion including a 1.5 mm radius notch, in accordance with an embodiment of the invention.

FIG. 7B is a comparison of finite element analysis simulations of a back iron portion of a finished motor component, the first back iron portion including no notch and the second back iron portion including a 3 mm radius notch, in accordance with an embodiment of the invention.

FIG. 7C is a comparison of finite element analysis simulations of a back iron portion of a finished motor component, the first back iron portion including no notch and the second back iron portion including a 1.5 mm radius notch, in accordance with an embodiment of the invention.

FIG. 7D is a comparison of finite element analysis simulations of a back iron portion of a finished motor component, the first back iron portion including no notch and the second back iron portion including a 3 mm radius notch, in accordance with an embodiment of the invention.

### DETAILED DESCRIPTION

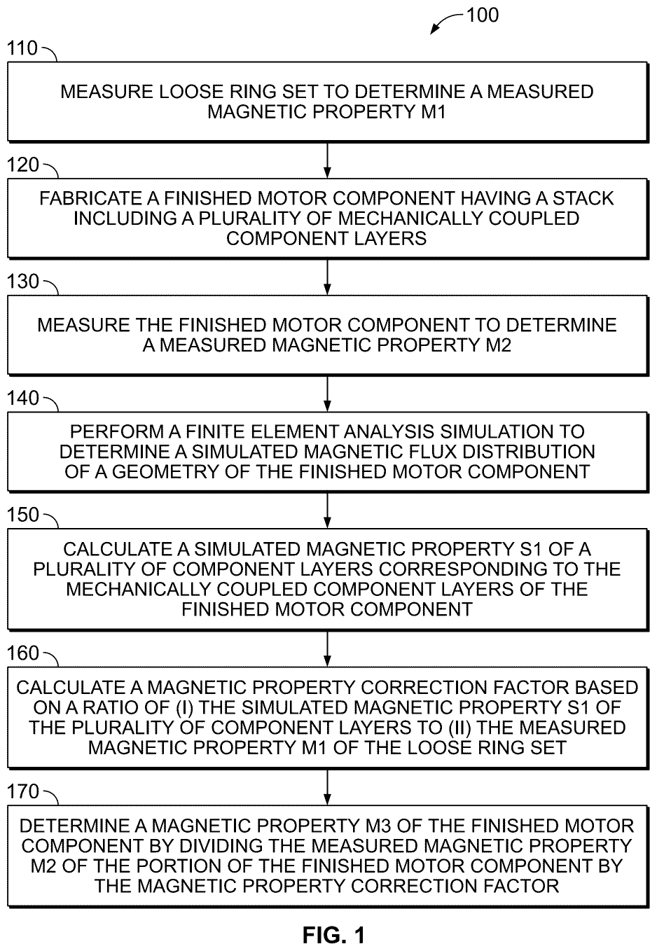

Referring to FIG. 1, a method 100 for determining a magnetic property of a finished motor component having a stack including a plurality of mechanically coupled component layers includes the following steps.

At step 110, a loose ring set including at least one loose ring is measured to determine a measured magnetic property M1 of the loose ring set. Each loose ring may have a same thickness and material parameters as at least one component layer of the stack of the finished motor component. In some embodiments, the measured magnetic property M1 is at least one of magnetic flux density, magnetic field strength, and core loss.

At step 120, the finished motor component having a stack is fabricated. In some embodiments, the finished motor component is a stator or a rotor.

At step 130, the finished motor component is measured to determine a measured magnetic property M2 of a portion of the finished motor component. In some embodiments, the measured magnetic property M2 is at least one of magnetic flux density, magnetic field strength, and/or core loss.

At step 140, a finite element analysis simulation is performed to determine a simulated magnetic flux distribution of a geometry of the finished motor component.

At step 150, a simulated magnetic property S1 of the plurality of component layers corresponding to the mechanically coupled component layers of the finished motor component is calculated using the simulated magnetic flux distribution. S1 may be a function of the measured magnetic property M1 of the loose ring set.

At step 160, a magnetic property correction factor is calculated, based on a ratio of (i) the simulated magnetic property S1 of the plurality of component layers to (ii) the measured magnetic property M1 of the loose ring set.

At step 170, a magnetic property M3 of the finished motor component is determined by dividing the measured magnetic property M2 of the portion of the finished motor component by the magnetic property correction factor. In some embodiments, the magnetic property M3 is at least one of magnetic flux density, magnetic field strength, and core loss. The magnetic property M3 may be determined using at least one of (i) a plurality of flux densities and (ii) a plurality of frequencies. When the magnetic property M3 includes core loss, determining the measured magnetic property M1 of the loose ring set includes calculating the core loss.

Although the exemplary method 100 depicts a particular sequence of operations, the sequence may be altered without departing from the scope of the present disclosure. For example, some of the operations depicted may be performed in parallel or in a different sequence that does not materially affect the function of the method 100. In other examples, different components of an example device or system that implements the method 100 may perform functions at substantially the same time or in a specific sequence.

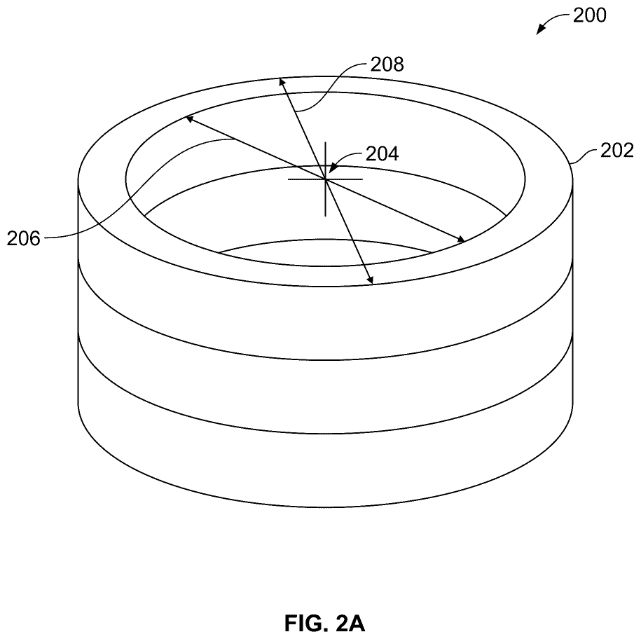

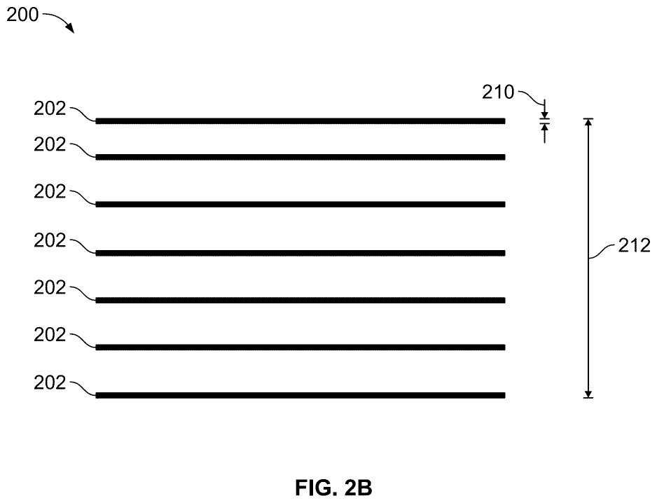

In particular, referring also to FIG. 2A and FIG. 2B, step 110 of the method 100 may include measuring a loose ring set 200 including at least one loose ring 202 to determine a measured magnetic property M1 of the loose ring set.

In some embodiments, each loose ring may include a soft magnetic material made from a combination of elements including but not limited to iron, cobalt, vanadium, niobium, carbon, nickel, silicon, samarium, copper, and/or aluminum. For example, each loose ring may be made from an iron-cobalt-vanadium alloy, e.g., Carpenter Technology Corporation, Hiperco® 50, having 48.5% cobalt, 1.9% vanadium, 0.05% niobium, 0.01% carbon, and balance iron. In other embodiments, each loose ring is made from a nickel-iron (NiFe) alloy, or a silicon-iron (SiFe) alloy. Each loose ring may be formed by cutting (i.e., stamping or laser cutting) a sheet of material (e.g., Hiperco® 50).

Each loose ring may be annular, with a hollow center 204, an inner diameter 206, and an outer diameter 208. The outer diameter of each loose ring may range from 0.5 inches to 14 inches, e.g., 1.5 inches. The inner diameter of each loose ring may range from 0.25 inches to 13.5 inches, e.g., 1.25 inches. A ratio of the inner diameter and the outer diameter of each loose ring may be greater than 0.83 and/or may follow guidance of Standard Test Method for Alternating-Current Magnetic Properties of Toroidal Core Specimens Using the Voltmeter-Ammeter-Wattmeter Method, ASTM A927/A927M-18, ASTM International (November 2022), incorporated by reference in its entirety herein. Relevant portions are included in the “Alternating-Current Magnetic Property Testing of Toroidal Core Specimens” section below. A thickness 210 of each loose ring may range from 0.004 inches to 0.019 inches, e.g., 0.006 inches. A height 212 of the loose ring set may range from 0.1 inches to 30 inches, e.g., 0.25 inches. The number of loose rings in the set may depend on a desired set height and thickness of each loose ring. For example, for a loose ring set to have a height of 0.2 inches made of loose rings that are each 0.004 inches thick, the set may include 50 loose rings.

A thickness of each loose ring may be uniform, e.g., vary by no more than 2-5%. Each loose ring may be substantially solid and smooth, with no teeth, indents, grooves, features, accents, or other details. Each loose ring may have a same thickness and material parameters of component layers (i.e., modified rings having teeth, slots, and/or other features) of the finished motor component. The loose rings may be kept together in a set during measuring and/or calculation through the use of a case. The case may be a cylindrical plastic case.

The measured magnetic property M1 may be at least one of magnetic flux density, magnetic field strength, and/or core loss. Each loose ring may have a uniform magnetic flux distribution. A magnetic flux density and/or a magnetic field strength of the loose ring set may be measured using a gaussmeter, a magnetometer, a fluxgate magnetometer, a proton precession magnetometer, and/or any other instrument capable of quantifying magnetic fields. The magnetic properties may be measured in accordance with test method standards, such as ASTM A927/A927M-18 (November 2022) and Standard Test Method for Direct Current Magnetic Properties of Low Coercivity Magnetic Materials, ASTM A773/A773M-21, ASTM International (February 2021), incorporated by reference in its entirety herein. Relevant portions of each standard are included in the “Alternating-Current Magnetic Property Testing of Toroidal Core Specimens” and “Direct-Current Magnetic Property Testing of Loose Ring Specimens” sections below. A magnetic flux density of the loose ring set may be in a range of 0 T to 2.45 T, e.g., 2 T. A magnetic field strength of the loose ring set may be in a range of 0 Oe to 400 Oe, e.g., 10 Oe. Core losses may be measured at different frequencies in the range of 1 Hz to 10,000 Hz, e. g., 400 Hz.

A core loss of the loose ring set may be measured or calculated. A core loss of the loose ring set may be measured using a test set up or method capable of quantifying core loss at different flux densities and frequencies. In some embodiments, direct power loss is measured and then core loss per unit weight is converted by using the material volume and density. In some embodiments, when the frequency of the magnetic field is 400 Hz and the peak magnetic flux density is 2 T for a loose ring with a thickness of 0.006 inches, the core loss of the loose ring set may be in the range of 10 W/kg to 200 W/kg. Note that the core loss of the loose ring set may depend on a thickness of each loose ring, a measurement frequency of the loose ring set, and an induction of the loose ring set. The core loss of the loose ring set may not depend on the height of the loose ring set, so long as the loose ring set has a compatible signal to noise ratio of at minimum 2:1.

Step 120 of the method 100 includes fabricating the finished motor component. The finished motor component may have a stack including a plurality of mechanically coupled component layers. Similarly to the loose rings discussed above, each component layer of the finished motor component may be formed by cutting (i.e., stamping, laser cutting, or any other process) a sheet of material. The mechanically coupled component layers may have similar material parameters and/or physical dimensions to each loose ring of the set. For example, the mechanically coupled component layers may be made from the same material as each loose ring. The mechanically coupled component layers may have the same inner diameter, outer diameter, and thickness as each loose ring, or the component layers may have a completely different geometry with a different number of teeth. The loose rings may follow ASTM standards as discussed above, as opposed to the mechanically coupled component layers which may have chosen parameters such as inner diameter length and/or outer diameter length. The height of the stack of the mechanically coupled component layers may be the same height as the loose ring set. The thickness of each mechanically coupled component layer may be the same thickness as each loose ring. The number of mechanically coupled component layers in the stack may be the same as the number of loose rings in the set, or the number of mechanically coupled component layers in the stack may be completely different as required per stator or rotor stack design.

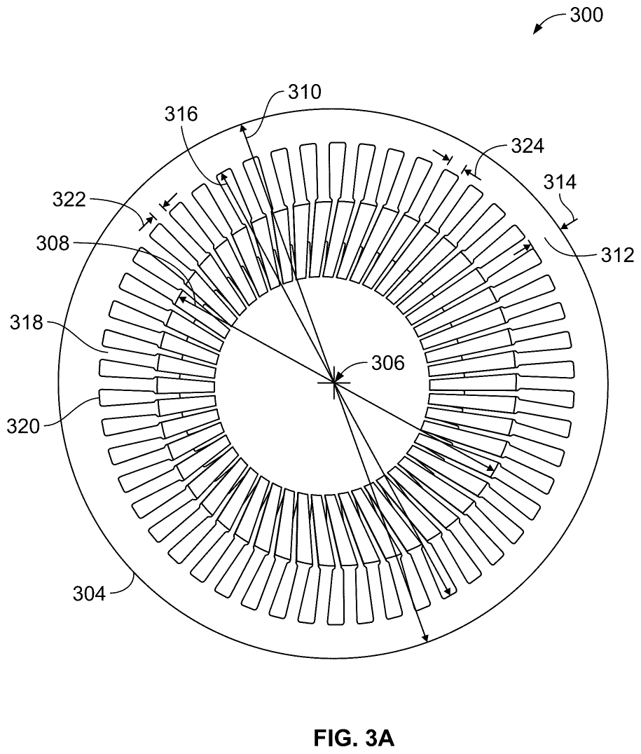

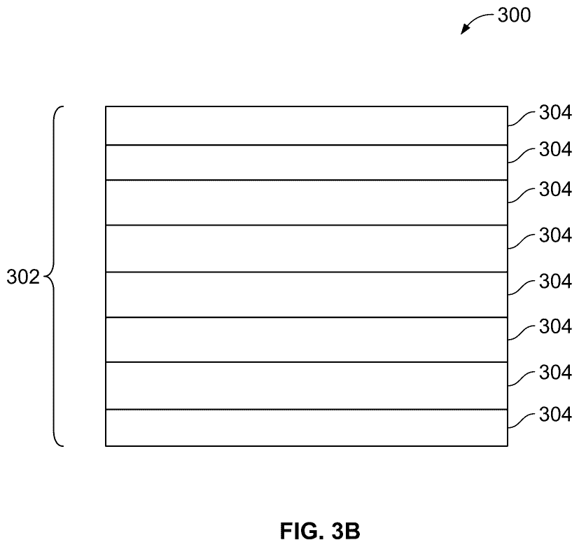

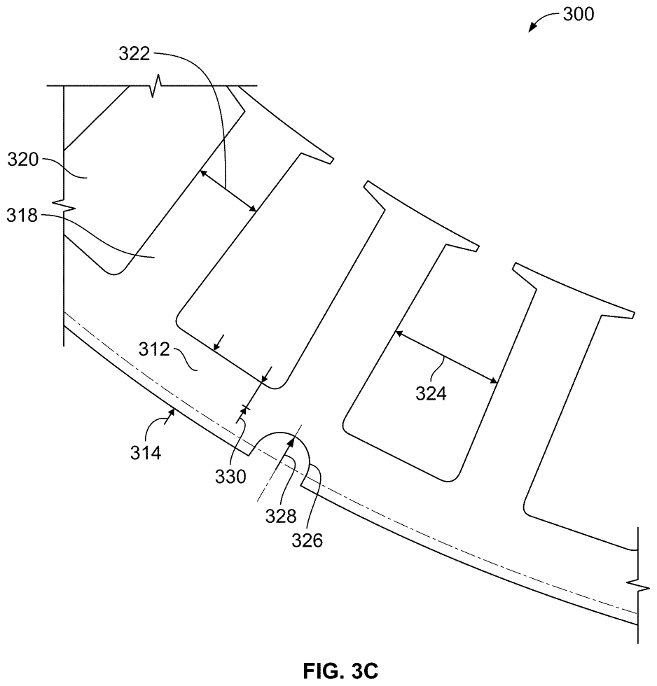

The finished motor component may be a stator 300, as shown in FIG. 3A-3C. The stator may have a stack 302 including a plurality of mechanically coupled component layers 304. The stator may be annular, with a hollow center 306, an inner diameter 308, an outer diameter 310, and a back iron portion 312. A back iron width 314 of the back iron portion of the stator may be defined as the difference between the outer diameter of the stator and an outer diameter 316 of teeth 318 of the stator (essentially, the border of the stator). In some embodiments, the stator may not have a back iron portion. The inner diameter of the stator may range from 0.1 inches to 30 inches, e.g., 3.5 inches. The outer diameter of the stator may range from 0.15 inches to 35 inches, e.g., 4 inches. The back iron width of the stator may range from 0.025 inches to 12 inches, e.g., 1 inches.

The stator may have teeth, and slots 320 between adjacent teeth. The number of teeth may range from 4 teeth to 500 teeth, e.g., 48 teeth. The teeth of the stator may be tapered and include an outer diameter and an inner diameter. The outer diameter of the stack including the teeth may range from 0.15 inches to 35 inches, e.g., 4 inches. The inner diameter of the stack including the teeth may range from 0.1 inches to 30 inches, e.g., 3.5 inches. A tooth width 322 of each of the teeth may range from 0.015 inches to 7.5 inches, e.g., 0.2 inches. In some embodiments, the tooth width is fixed. In some embodiments, the tooth width tapers (i.e., the tooth width gradually increases from inner diameter to outer diameter of the stack). The teeth may be circular, ovular, square, rectangular, trapezoidal, or any other shape. The teeth may have straight edges, rounded edges, or a combination of straight and rounded edges. In some embodiments, the measurements of each tooth are the same, while in other embodiments, the measurements of the teeth may differ (for example, in an alternating pattern).

The slots of the stator may be tapered and include an outer diameter and an inner diameter. An outer diameter of the slots may be the same length as the outer diameter of the teeth. An inner diameter of the slots may be the same length as the inner diameter of the teeth, which may be the same as the inner diameter of the stator. The number of slots may range from 4 slots to 500 slots, e.g., 48 slots. A slot width 324 of each slot may range from 0.1 inches to 7.5 inches, e.g., 0.5 inches. In some embodiments, the measurements of each slot are the same, while in other embodiments, the measurements of the slots may differ (for example, in an alternating pattern).

The stator may include, alternatively or in addition to the teeth and slots, grooves, notches, or other features. For example, the stator may include one or more notches 326 along its outer diameter and/or back iron portion. The radius 328 of a notch may range from 0.02 inches to 11.5 inches, e.g., 0.1 inches. When the stator includes one or more notches, the back iron portion may include an effective back iron width 330, which is the radius of the notch subtracted from the back iron width.

The finished motor component may be a rotor. The rotor may include a stack having a plurality of mechanically coupled component layers. The rotor may be annular, with a hollow center, an inner diameter, and an outer diameter. In some embodiments, the rotor includes a back iron portion. A back iron width of the back iron portion of the rotor may be defined as the difference between the outer diameter of the rotor and an outermost edge of slots of the rotor (essentially, the border of the rotor). The inner diameter of the rotor may be smaller than the inner diameter 308 of the stator 300, and may range from 0.05 inches to 29 inches, e.g., 1.5 inches. The outer diameter of the rotor may be smaller than the outer diameter 310 of the stator 300, and may range from 0.075 inches to 30.75 inches, e.g., 3.4 inches.

The rotor may include a pattern of symmetrical U-shaped slots applied to each of its quadrants. In other embodiments, slots may be V-shaped or a different pattern. The rotor may include, alternatively or in addition to a slot pattern, teeth, grooves, or other features. For example, the rotor may include one or more notches along its outer diameter and/or back iron portion. The radius of a notch may range from 0.02 inches to 11.5 inches, e.g., 0.1 inches.

The stator or rotor stack may include 18 to 7500 mechanically coupled component layers, depending on a desired thickness of the finished motor component (e.g., 0.1 inches to 30 inches) and the thickness of the mechanically coupled component layers (e.g., 0.004 inches to 0.019 inches). A thickness of each component layer of the finished motor component may be uniform, e.g., vary by no more than 2-5%. The stack may be formed by one or more of following processes: epoxy bonding/curing, interlocking, laser welding, or clamping. Once the component layers of the finished motor component are mechanically bonded, they may not be easily separated from each other.

Also referring to FIG. 3A-3C, step 130 of the method 100 includes determining a measured magnetic property M2 of a portion of the finished motor component. In some embodiments, the portion of the finished motor component is a back iron portion 312. In some embodiments, the portion of the finished motor component is a tooth 318 extending radially from the back iron portion. In some embodiments, the portion is a portion of a cylindrical body of the finished motor component. The measured magnetic property M2 may be at least one of magnetic flux density, magnetic field strength, and/or core loss. Due to teeth, slots, notches, or other features included in the finished motor component along with their dimensions, the finished motor component may not have a uniform flux distribution.

A magnetic flux density and/or a magnetic field strength of the portion of the finished motor component may be measured as discussed above with respect to measurement of the loose ring set. A magnetic flux density of the portion of the finished motor component may be in a range of 0 T to 2.45 T, e.g., 2 T. A core loss of the portion of the finished motor component may be measured or calculated, as discussed above with respect to measurement of the loose ring set.

Step 140 of the method 100 includes performing a finite element analysis simulation to determine a simulated magnetic flux distribution of a geometry of the finished motor component. Suitable software for generating the geometry of the finished motor component and performing a finite element analysis simulation are, e.g., Siemens MagNet or Ansys Maxwell. The geometry of the finished motor component may be input into the software, including measurements, features, and material properties of the finished motor component. Material properties that may be specified in the software may include density, resistivity, and thickness. The material properties and parameters may be based on properties and parameters of the loose ring set, of which M1 was measured.

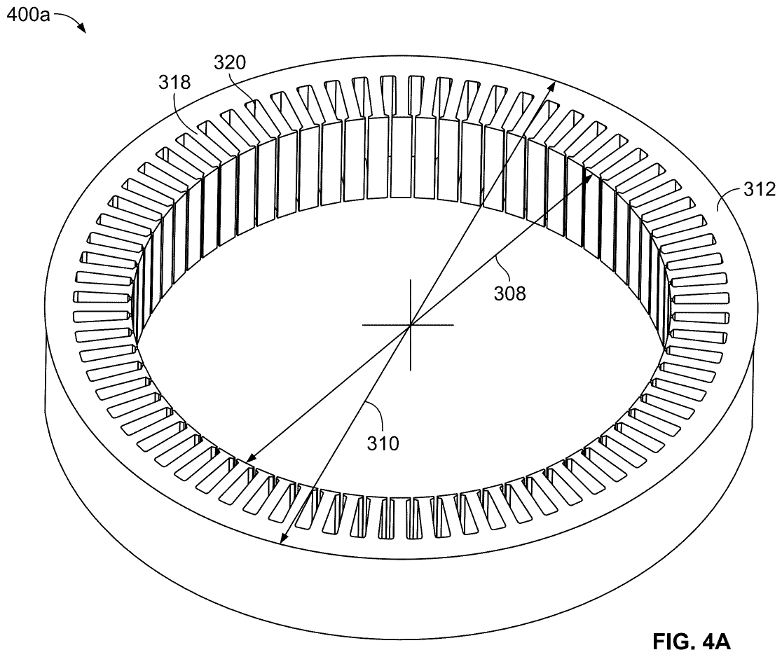

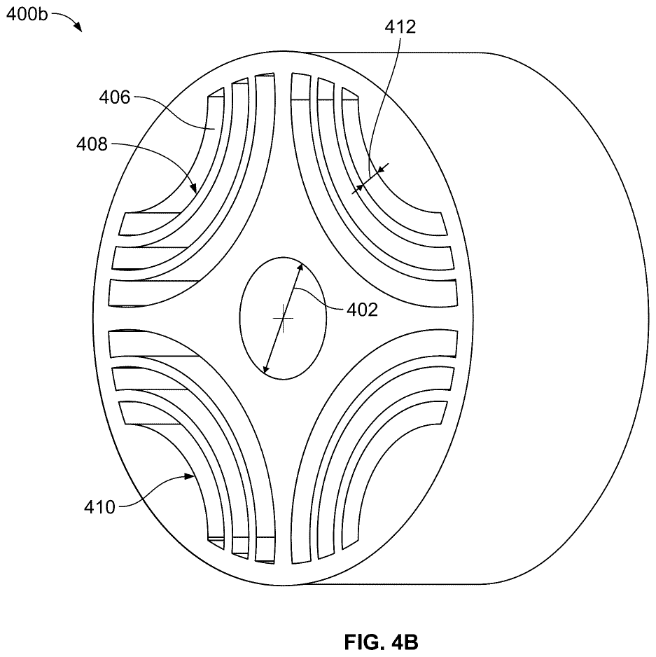

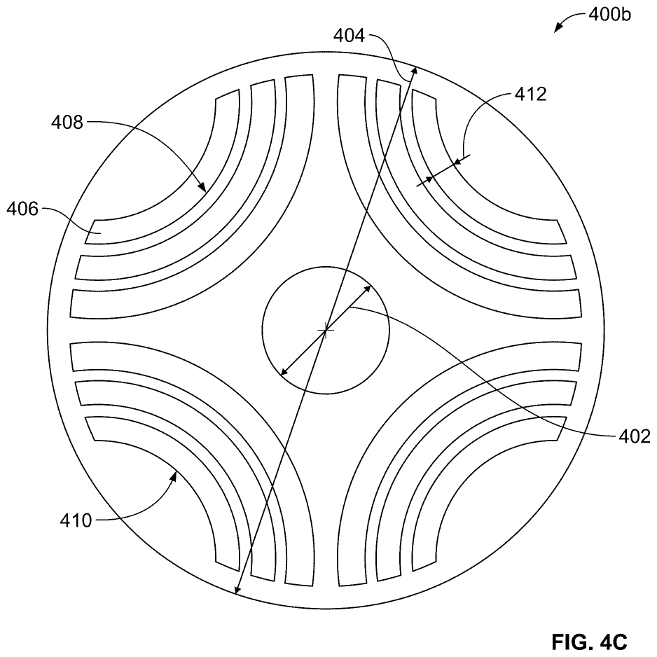

The simulated geometry of a finished motor component may be a stator 400a, as shown in FIG. 4A. The simulated geometry of the stator may include values and features that correspond to the finished motor component stator. For example, the inner diameter 308, the outer diameter 310, the back iron portion 312, the number of teeth 318, the shape of the teeth, the outer diameter of the teeth, the inner diameter of the teeth, the teeth width, the number of slots 320, the shape of the slots, the outer diameter of the slots, the inner diameter of the slots, the slot width, the number of notches, and/or the radius of notches may be input to the software to simulate the stator. The finite element analysis simulation may be performed in one or more different regions of the stator magnetically excited. The finite element analysis simulation may be performed for different magnetic excitement scenarios at different regions of the stator for a specific design. For example, the simulation may provide a simulated magnetic flux distribution based on the back iron portion of the stack magnetically excited by windings. Alternatively, the simulation may provide a simulated magnetic flux distribution based on the back iron portion and the teeth of the stack magnetically excited by windings.

The simulated geometry of a finished motor component may be a rotor 400b, as shown in FIG. 4B and FIG. 4C. The simulated geometry of the rotor may include values and features that correspond to a finished motor component rotor. For example, an inner diameter 402, an outer diameter 404, number of slots 406, shape of the slots, an outer radius 408 of slots, an inner radius 410 of slots, slot width 412, number of notches, and/or radius of notches may be input to the software to simulate a rotor. The finite element analysis simulation may be performed for different regions of the rotor magnetically excited. The finite element analysis simulation may be performed for different magnetic excitement scenarios at different regions of the rotor for a specific design. For example, the simulation may provide a simulated magnetic flux distribution based on the portion of the stack magnetically excited by windings. Alternatively, the simulation may provide a simulated magnetic flux distribution based on the portion and the slots of the stack magnetically excited by windings.

The finite element analysis simulation may provide a visual gradient and visual gradient scale indicating the strength of the simulated magnetic flux distribution. For example, a scale of low to high magnetic flux distribution may be indicated by colors ranging from dark blue to red, respectively, with the middle range colors being light blue, green, yellow, and orange, respectively.

The finite element analysis simulation may volumetrically quantify a simulated magnetic flux distribution. The simulated magnetic flux distribution may be impacted by a presence of any feature, such as teeth or a notch, in the portion of the finished motor component. A feature may result in either flux dilution or flux densification. Depending on the region driven to magnetic excitement, there can be inhomogeneity in the flux density across the volume of the stator or rotor stack.

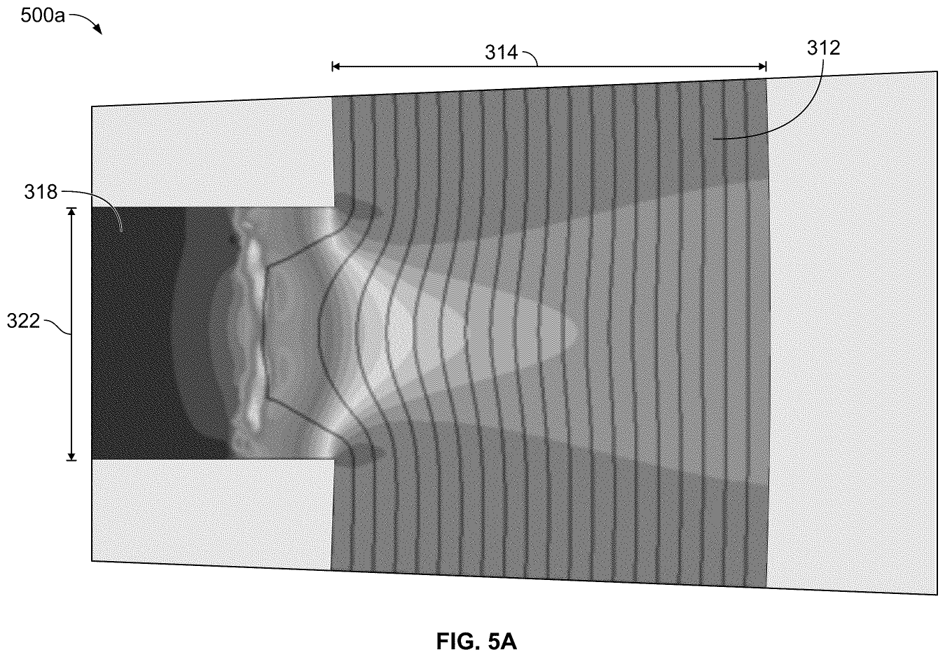

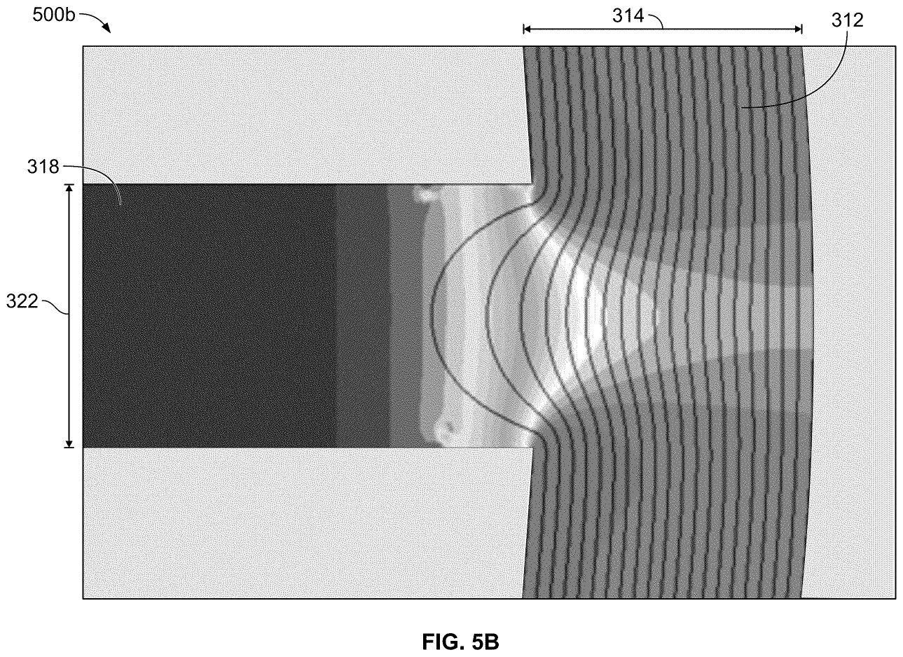

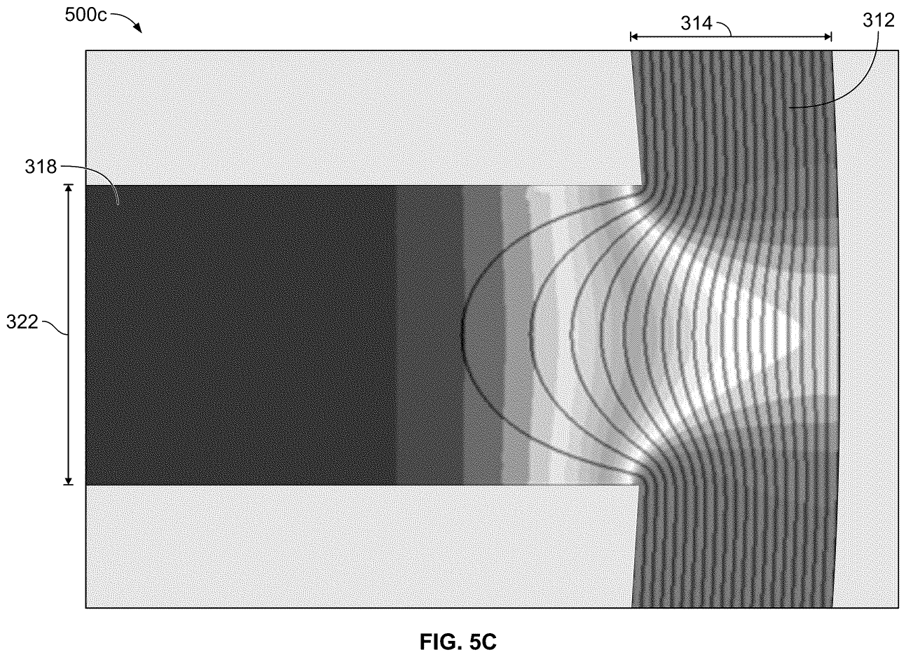

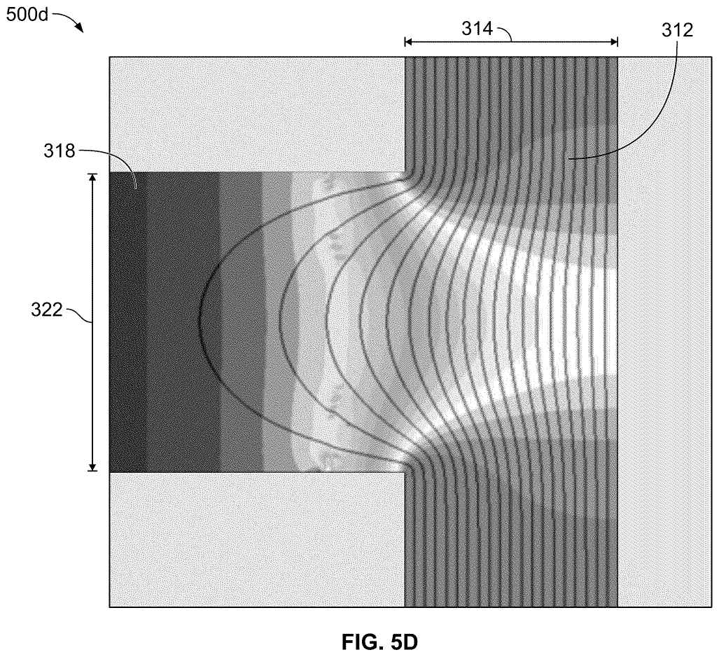

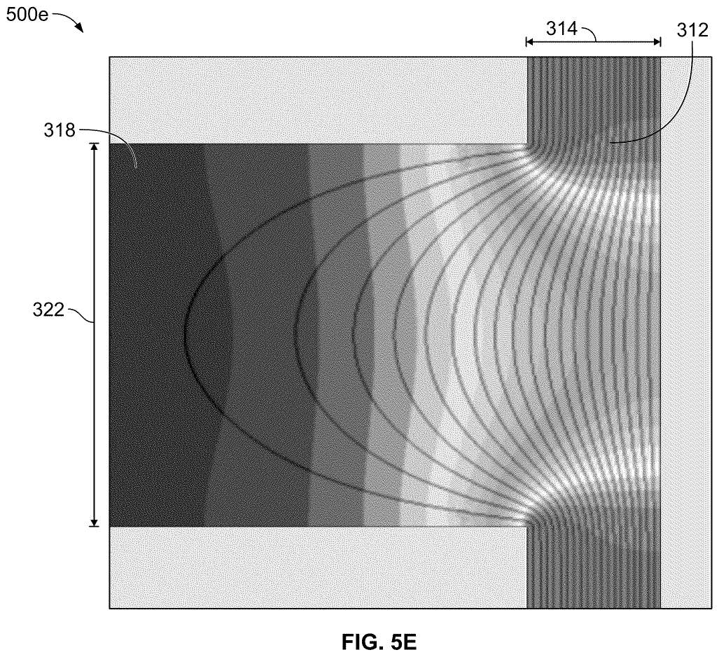

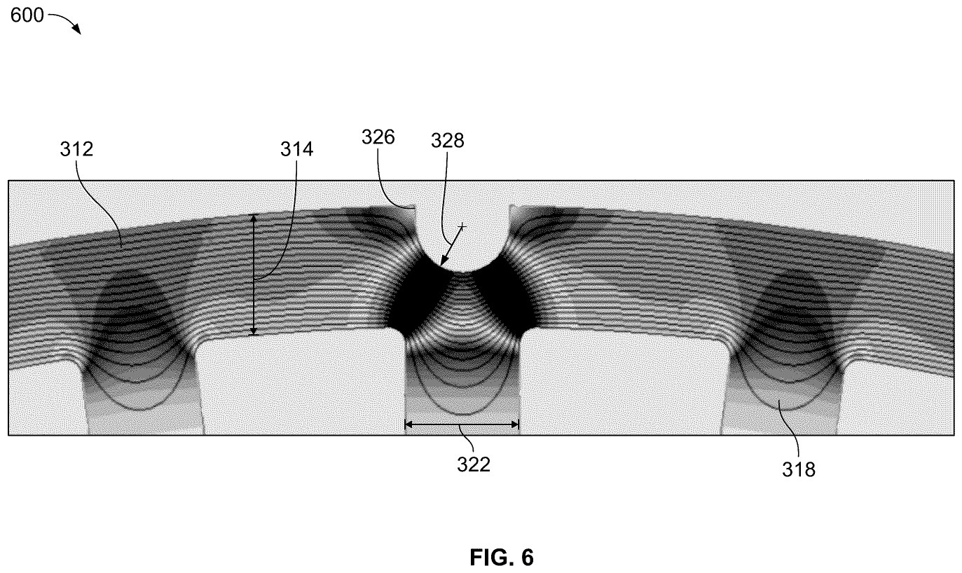

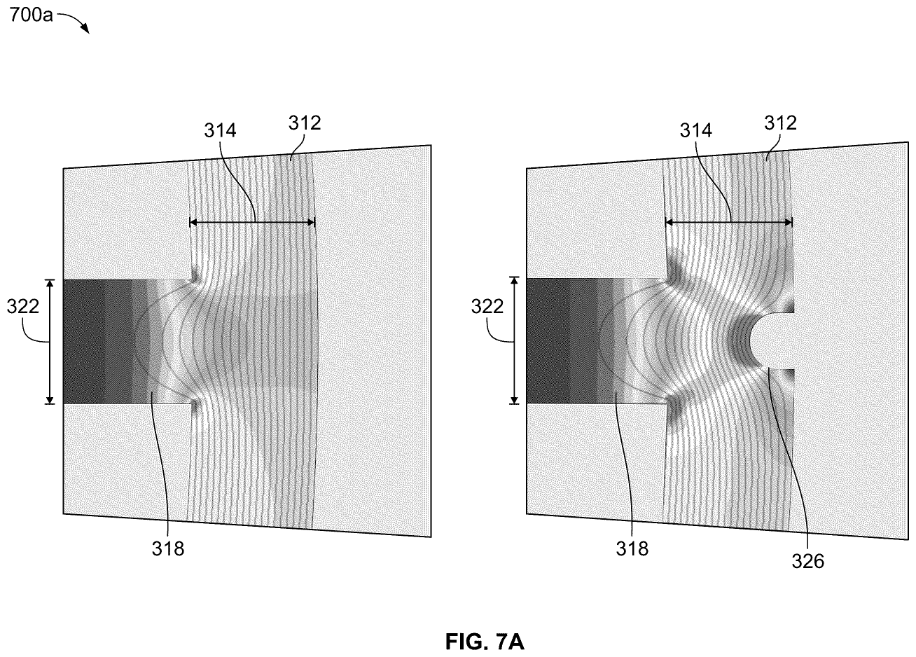

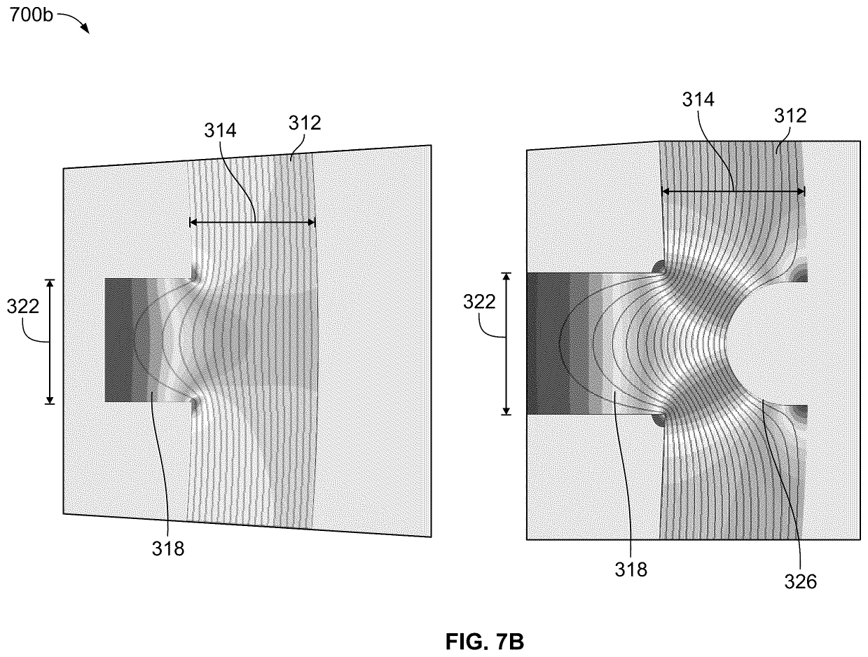

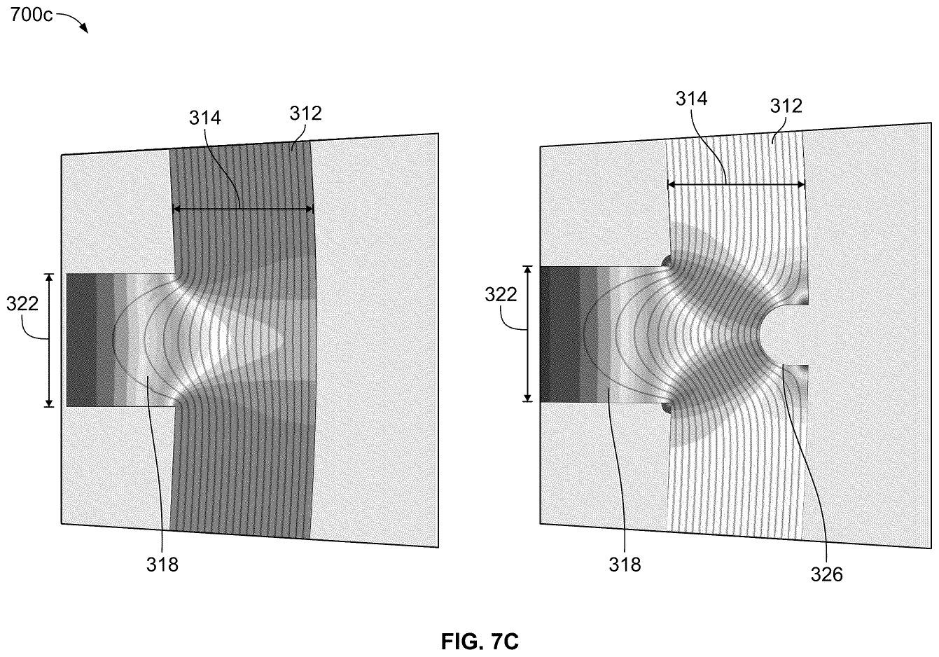

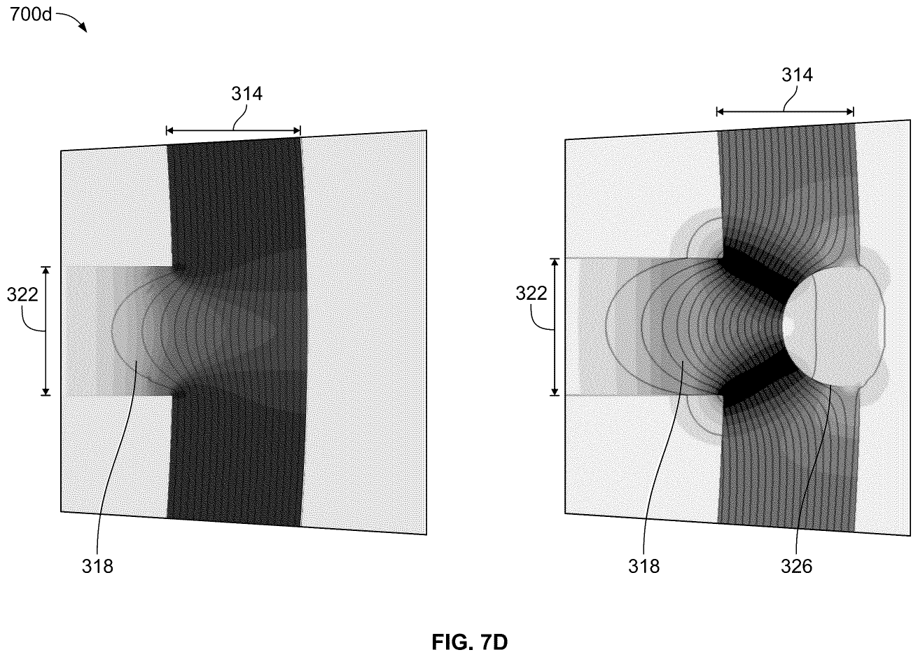

For example, teeth may cause an inhomogeneous flux distribution 500a, 500b, 500c, 500d, 500e in the back iron portion of a stator, examples of which are shown in FIG. 5A to 5E. A higher tooth width 322 to back iron width 314 ratio (t:d) may result in higher flux dilution. A lower tooth width to back iron width ratio may result in lower flux dilution. A notch 326 may result in flux densification 600, as shown in FIG. 6. Comparisons of the simulated magnetic flux distributions of back iron portions with and without a notch 700a, 700b, 700c, 700d are shown in FIG. 7A to 7D.

The average magnetic flux density of a portion of the finished motor component is lower when the portion includes a notch since the notch inhibits the flow of the magnetic flux, resulting in an inhomogeneity in the magnetic flux. However, core loss of the portion of the finished motor component may increase when one or more parts of the portion increases in magnetic flux density (which may be as a result of one or more notches). A back iron portion effective width may be defined as the difference between a back iron width and a radius of a notch, and the back iron portion effective width may be used to calculate core loss when a back iron portion contains one or more notches. For a finished motor component included a back iron portion, the larger the radius of a notch, the smaller a back iron portion effective width and the larger the core loss of the back iron portion around the notch region. Factors that may impact the simulated magnetic flux distribution include an outer diameter of the finished motor component, a back iron width, a number of teeth, a width of each tooth, a tooth width to back iron width ratio, a slot width, a notch location, a notch radius, and a number of notches. The higher the number of notches in a finished motor component, the lower the average magnetic flux density. However, in some portions of the finished motor component, local flux density can be much higher than an average flux density and those regions can have higher core loss. In step 130, the measurement process assumes uniform flux distribution in the portion of the finished motor component, and delivers a specific core loss value for certain induction/flux density at a specific frequency. However, in actuality, the specific core loss originates from a distribution of flux densities, which is captured in the finite element analysis simulation.

The finite element analysis simulation may calculate the anticipated volume percentage of the simulated magnetic flux distribution. For example, a first magnetic flux distribution value of 80% of the total volume of the finished motor component, a second magnetic flux distribution value of 15% of the total volume of the finished motor component, and a third magnetic flux distribution value of 5% of the total volume of the finished motor component. The magnetic flux distribution may range from 0 T to 2.45 T, e.g., 0.88 T.

Step 150 of the method 100 includes calculating a simulated magnetic property S1 of a plurality of component layers corresponding to the mechanically coupled component layers of the finished motor component using the simulated magnetic flux distribution. S1 may be a function of the measured magnetic property M1 of the loose ring set.

The simulated magnetic flux distribution from step 140 may be used to calculate the simulated magnetic property S1, which may be core loss. Core loss of the portion of the finished motor component may be measured or calculated using methods as discussed above with respect to measurement of the loose ring set. The software may calculate core loss for a percent volume of the total volume of the finished motor component. For example, a first core loss value of 80% of the total volume of the finished motor component, a second core loss value of 15% of the total volume of the finished motor component, and a third core loss value of 5% of the total volume of the finished motor component. Once the core loss has been calculated for each percent volume of the geometry of the finished motor component, the weighted average simulated core loss S1 may be calculated.

Step 160 of the method 100 includes calculating a magnetic property correction factor based on a ratio of (i) the simulated magnetic property S1 of the plurality of component layers to (ii) the measured magnetic property M1 of the loose ring set. The magnetic property correction factor is equal to S1 divided by M1. This magnetic property correction factor quantifies the difference in a magnetic property between a simulated finished motor component layer and a physical loose ring having a smooth profile, i.e., no notches or teeth. M1 may be greater or lower than S1 because the physical loose ring has a smooth profile with no features, while the simulated finished motor component has teeth, notches, or a non-smooth profile. A higher tooth width to back iron width ratio and corresponding higher flux dilution from step 140 may result in a higher correction factor. For example, the magnetic property correction factor for a simulated finished motor component including only teeth may be greater than 1. In another example, the magnetic property correction factor for a simulated finished motor component including only notches may be less than 1.

Step 170 of the method 100 may include determining a magnetic property M3 of the finished motor component by dividing the measured magnetic property M2 of the portion of the finished motor component by the magnetic property correction factor. The magnetic property correction factor can be applied to the same magnetic property from which the magnetic property correction factor was derived, or the magnetic property correction factor may be applied to a different magnetic property. For example, if the magnetic property correction factor was calculated using magnetic flux density values, the same magnetic property correction factor may also be used to calculate core loss, or a different correction factor may be used to calculate the core loss.

### Alternating-Current Magnetic Property Testing of Toroidal Core Specimens

From Standard Test Method for Alternating-Current Magnetic Properties of Toroidal Core Specimens Using the Voltmeter-Ammeter-Wattmeter Method, ASTM A927/A927M-18, ASTM International (November 2022)

### 3. Significance and Use

3.2 Specimen size typically ranges from 1 in. to 1.25 in. [25.4 mm to 31.8 mm] in inside diameter to 1.5 in. [38.1 mm] in outside diameter with weights ranging from 30 g to 60 g. Provided the test equipment is suitably chosen, there is no obvious limit to the overall size of core that can be tested. If basic material properties are desired, then the requirements of 5.1 must be observed.

### 5. Test Specimen

5.1 The test specimen must be either a stack of toroidal (washer ring) laminations formed by punching, machining, or etching or a toroidal tape wound core. For measurement of basic material properties, the ratio of inside to outside diameter must be 0.82 or greater.

### 6. Procedure

6.1 The test specimen should be heat treated after fabrication. Bent or otherwise damaged laminations or tape cores shall be discarded.
6.2 The core shall be weighed to an accuracy of +0.1% or better and the inside and outside diameters measured to an accuracy of 0.1% or better.
6.3 The laminations or tape core should be enclosed in a rigid, nonconductive case (core box) or placed in a suitable fixture to avoid winding stresses. The test core should fill the core box or fixture as fully as possible to minimize air flux.
6.4 Primary and secondary windings, N₁ and N₂, are applied; the secondary winding should be applied first. Both windings should be uniformly wound over the circumference of the toroid. The secondary winding may use finer diameter wire than the primary winding, which should be of sufficient diameter to carry the magnetizing current without overheating. Alternately, a fabricated magnetizing fixture may be used provided the windings are uniformly distributed over the length of the core.
6.5 If the number of turns on the secondary winding is not equal to the number of turns on the primary winding, additional circuitry such as amplifiers or attenuators may be required to control the “loop gain” in the waveform feedback loop. Failure to control the “loop gain” will normally result in power supply instability.
6.6 The flux voltage, Er, induced in the secondary winding, N₂, at the required magnetic flux density, B, shall be computed using the equation found in 7.2 or 8.2.
6.7 The test specimen is connected to the test apparatus and demagnetized. Demagnetization must be done by smoothly reducing the magnetizing current starting from a magnetic flux density above the knee of the magnetization curve and at the test frequency.
6.8 The magnetizing current is increased to obtain the flux voltage corresponding to the lowest required magnetic flux density.
6.9 The form factor of the secondary voltage is computed by dividing the rms secondary voltage by the flux voltage. The form factor must be within ±1% of the value for a sine wave for testing conducted in accordance with this test method. Once test conditions have been established for a particular test core and material, measurement of the form factor is optional.
6.10 For core loss determination, read and record the power from the wattmeter.
6.11 For specific exciting power determination, read and record both the rms exciting current and rms secondary voltage as displayed on the wattmeter or other rms voltmeters.
6.12 For peak permeability determination, read and record the voltage drop across the current-sensing resistor using the peak-reading voltmeter.
6.13 Repeat 6.8 through 6.12 for all test points in order of increasing magnetic flux density. If the required magnetic flux density is exceeded without acquiring the needed data, the core must be demagnetized before repeating the measurement.

### 8. Calculation (SI Units)

8.1 The cross-sectional area of the test specimen is computed from the mass of core, the density of the material, and the magnetic path length. For a toroidal core the magnetic path length, Iₘ, is equal to the mean circumference or:

$${l}_{m} = \frac{π ( {d}_{0} + {d}_{i} )}{2} \qquad ( 7 )$$

where:
dₒ-outside diameter, m and
dᵢ=inside diameter, m.

The cross-sectional area, A, in square metres, is then:

$$A = \frac{m}{δ {l}_{m}} \qquad ( 8 )$$

where:
m=core mass, kg, and
δ=density, kg/m³.
8.2 Flux Voltage—The flux voltage corresponding to a given magnetic flux density (assumed to be sinusoidal) is:

E_{f}=\sqrt{2}πBAN₂f (9)
where:
E_{f}=flux voltage induced in winding N₂, V;
B magnetic flux density, T;
A cross-sectional area of core, m²;
N₂=number of secondary turns; and
f=frequency, Hz.
8.3 Specific Core Loss—The core loss per kilogram is:

$${P}_{c ( B ; f )} = \frac{( \frac{{N}_{1}}{{N}_{2}} ) ( W - K )}{m} \qquad ( 10 )$$

where:
P_{c(B:f)}=specific core loss at magnetic flux density B and frequency f, W/kg;
N₁=number of primary turns;
N₂=number of secondary turns;
W=power loss indicated by the wattmeter, W;
K=correction factor for losses due to the wattmeter, W; and
m=mass of test core, kg.
The correction factor in electronic wattmeters tends to be very small and is usually negligible. Refer to the wattmeter operating manual for specific instructions on computing this correction factor.
8.4 Specific Exciting Power—The specific exciting power is calculated from the rms value of exciting current and rms secondary voltage with all other secondary burden either subtracted or removed. The latter condition usually applies when high-input impedance-measurement equipment is used. The equation is:

$${P}_{z ( B ; f )} = \frac{( \frac{{N}_{1}}{{N}_{2}} ) VI}{m} \qquad ( 11 )$$

where:
P_{z(B;f)}=specific exciting power at magnetic flux density B and frequency f, VA/kg;
N₁=number of primary turns;
N₂=number of secondary turns;
V=rms value of secondary voltage, V;
I-rms value of exciting current, A; and
m=mass of test core, kg.
8.5 Relative Peak ac Permeability—The relative ac peak permeability is calculated as:

$${μ}_{p} = \frac{B}{{H}_{p} {μ}_{0}} = \frac{{BRI}_{m}}{{N}_{1} {E}_{p} {μ}_{0}} \qquad ( 12 )$$

where:
μₚ=peak ac permeability;
B=magnetic flux density, T, which is equivalent to the test magnetic flux density for sinusoidal waveforms;
Hₚ=peak magnetic field strength, A/m;
μ₀=magnetic constant equal to 4π×10⁻⁷ H/m;
N=number of primary turns;
Eₚ=peak voltage read across the current-sensing resistor, V;
R=resistance of the current-sensing resistor, Ω; and
Iₘ=magnetic path length, m.

### Direct-Current Magnetic Property Testing of Loose Ring Specimens

From “Standard Test Method for Direct Current Magnetic Properties of Low Coercivity Magnetic Materials,” ASTM A773/A773M-21, ASTM International, February 2021

### 15. Procedure

15.1 The following test procedure is representative of most analog and digital hysteresigraphs. The details of some operating steps may vary with the particular make and model of hysteresigraph. However, the general test procedures are similar in all units. The following procedure covers manual current sweeping, automatic current sweeping, and automatic current sweeping with symmetrical tracing.
15.2 Setup—The procedures of 15.2.1-15.2.6 should be observed for all methods of current sweep.
15.2.1 Before beginning a test, allow a minimum warm-up period for all apparatus and instrumentation as recommended by the equipment manufacturer.
15.2.2 Connect the specimen, observing polarity so that the first quadrant of the hysteresis loop is being measured on initial application of the magnetizing current. (It is imperative that proper polarity be established before demagnetization of the test specimen.) Some computer-controlled equipment automatically corrects the polarity if it is reversed.
15.2.3 Before testing, demagnetize the specimen by establishing a magnetic field strength sufficiently large to reach a point well above the knee of the magnetization curve. Then, while continuously cycling the magnetization between + and − polarity, slowly reduce the magnetizing current to zero. (In the demagnetization process, down-switching of voltage taps to reduce current may result in current surges. It is advisable to select voltage sources and controls that have the ability to reduce current to a low value without switching taps, preferably to a current level that does not exceed a value of 0.1 times the coercivity of the material.)
15.2.4 For the B measurement, set the B integrator range and scaling circuitry or software so that B is displayed or recorded, or both, directly.
15.2.5 For the H measurement, select the appropriate current measuring resistor (current range) and set the scaling circuitry or software so that His displayed or recorded, or both, directly.
15.2.6 Before starting the current sweep, adjust the integrator drift to a minimum. It is recommended that the drift be observed for a period approximately equal to the expected measuring time. Many modern integrating fluxmeters automatically check and adjust for minimum drift in the course of normal operation.
15.4 Automatic Sweep Method—In obtaining magnetization and hysteresis data by hysteresigraph methods, automatic sweeps are preferable because of better control of the sweep current for tracing smooth loops. If a specimen is completely demagnetized, it is possible to obtain initial magnetization curves and symmetrical hysteresis loops.
15.4.1 Before testing, follow the setup procedure described in 15.2.1-15.2.6.
15.4.2 Switch the magnetizing current controller to the automatic mode.
15.4.3 Select the appropriate current range (current measuring resistor) and set the H-scaling control or software to give the desired full-scale magnetic field strength.
15.4.4 Set the magnetizing current control or software to give the desired peak magnetic field strength, which may be less than full scale magnetic field strength.
15.4.5 Set the sweep speed of the controller to 20 s or longer per loop, adjust the integrator drift to a minimum, and, if used, place the pen of the X-Y recorder in the down position at the origin. If constant flux change (dB/dt) sweeping is used, the maximum sweep speed shall be 2 kG [0.2 T] per second. Significantly slower sweep speeds may be required for materials with relative permeability greater than 10 000 such as some Ni—Fe alloys.
15.4.6 Begin the current sweep. If the specimen is completely demagnetized, an initial magnetization+curve will be measured in the first quadrant to (+Hₘ, +Bₘ), then His automatically reduced and the measurement proceeds to (0, +Bᵣ). The current sweep is automatically switched in polarity, and the second and third quadrants are measured. At (−Hₘ,−Bₘ) the current sweep is again reduced, and the remaining half of the hysteresis loop is measured. It is advisable to record at least two complete loops to ascertain if significant drift has occurred during the measurement.
15.4.7 If the loop determined in 15.4.6 is symmetrical about the origin, the curve from the origin to Hm is the initial magnetization curve; any point on the major loop is valid and may be read directly. If the major loop is only moderately displaced, approximate values for points Bᵣ, H_{cB}, Hₘ, Bₘ or any other point on the loop may be obtained by averaging corresponding positive and negative values. However, if the loop is significantly displaced as a result of incomplete demagnetization, the initial magnetization curve is not valid and the permeabilities cannot be accurately determined.
15.4.8 If the H_{cB} value of the specimen is very small relative to Hₘ so that H_{cB} and Bᵣ cannot be resolved with high accuracy, the H scale may be expanded to give increased sensitivity for accurate reading of Bᵣ and H_{cB}. Follow the procedures as described in 15.3.5.
15.4.9 Minor hysteresis loops are obtainable at any point of the major loop by reversing the current sweep in incremental amounts.
   16. Calculations when Using Permeameter Procedures
16.2 In permeameters where the B-coil is a compensated coil set (measures either the intrinsic flux density, Bᵢ, or the magnetic polarization, J), the area of the specimen can be smaller than the area of the coil without requiring any air flux compensation. In permeameters where an uncompensated B-coil is used and the area of the B-coil is much larger than the test specimen, a correction, K₂, is required. Make this correction as follows:
16.2.1 Determine the correction, K₂, as follows:

$${K}_{2} = \frac{{a}_{c} - {A}_{c}}{{A}_{c}} \qquad ( 6 )$$

where:
a_{c}=cross-sectional area of B-coil, cm² [m²] and
A_{c}=cross-sectional area of test specimen, cm² [m²].
16.2.2 Determine the magnetic flux density in the test specimen, B, as follows:

B=B_{obs}−K₂μ₀H (7)
where:
B=magnetic flux density, G [T];
B_{obs}=measured magnetic flux density, G [T];
H=magnetic field strength, Oe [A/m]; and
μ₀=magnetic constant=1 (cgs-emu) or 4π×10⁻⁷ H/m (SI).
   19. Calculations when Using Ring Test Procedures
19.1 The average magnetic field strength applied to the test specimen by the current through the magnetizing winding is determined from the equation:

$$H = \frac{{K}_{3} NI}{{l}_{m}} \qquad ( 9 )$$

where:
H=magnetic field strength, Oe [A/m];
N=number of turns in magnetizing winding N₁;
I=current through the magnetizing winding, [A];
Iₘ=mean magnetic path length, cm [m]; and
K₃=constant equal to 0.4π for cgs-emu units and 1 for SI units.
19.1.1 For a ring specimen, Iₘ is determined from the mean circumference. For the Epstein frame, the mean magnetic path length is assumed to be 94 cm (940 mm), and the equation for the 700-turn Epstein test frame is as follows:

$$H = \frac{0.4 π \times 700 I}{94} = 9.358 I Oe \qquad ( 10 )$$

$$H = 744.7 I [ A / m ]$$

19.1.2 For the 352-turn Epstein frame:

$$H = \frac{0.4 π \times 352 I}{94} = 4.706 I Oe \qquad ( 11 )$$

$$H = 374.5 I [ A / m ]$$

19.2 When nonlaminated test specimens have very smooth surfaces and precise uniform dimensions, the cross-sectional area shall be determined from physical measurements. In all other cases, the effective test specimen area shall be determined from measurements of mass, length, and density as follows:

$${A}_{c} = \frac{m}{l δ} \qquad ( 12 )$$

where:
A_{c}=test specimen cross-sectional area, cm² [m²];
m=test specimen mass, g [kg];
l=test specimen length, cm [m]; and
δ=density of test specimen material, g/cm³ [kg/m^{3]}.
19.2.1 For the Epstein test frame:

$${A}_{c} = \frac{m}{4 l δ} \qquad ( 13 )$$

where:
A_{c}=test specimen cross-sectional area, cm² [m²];
m=test specimen mass, g [kg];
l=Epstein test specimen length, cm [m]; and
δ=density of test specimen material, g/cm³ [kg/m^{3]}.
19.3 The Epstein test frame coils are built considerably larger than the test specimen cross-sectional area. To avoid the need for manual air-flux correction, a compensating mutual inductor is built into the test frame. This means that the magnetic flux density measurements are either intrinsic magnetic flux density, Bᵢ, or magnetic polarization, J, depending on the system of units used. To obtain magnetic flux density, B, the following equations must be used:

B=Bᵢ+μ₀H (14)

B=J+μ₀H (15)
where:
B=magnetic flux density in test sample, G [T];
Bᵢ=intrinsic magnetic flux density in test specimen, G;
J=magnetic polarization, T;
H magnetic field strength, Oe [A/m]; and
μ₀=magnetic constant=1 (cgs-emu) or 4π×10⁻⁷ H/m (SI).
19.4 When ring testing is conducted at high magnetic field strength, and particularly when the secondary winding surrounds an appreciable air flux in addition to the core flux, the test values may be corrected for air flux as follows. Wind a duplicate set of windings around a nonmagnetic core of identical size. Connect the magnetizing windings in series aiding and the secondary windings in series opposition. This provides air-flux compensation and the measurements become either intrinsic magnetic flux density, (Ai, or magnetic polarization, J, as for the Epstein test frames. This method is usually more accurate than estimating the air-flux linking the secondary winding.
19.5 When the air-flux corrections must be calculated from estimated winding areas, the procedures described in 16.2.1 and 16.2.2 should be used.

### Example

The simulated magnetic flux distribution example in Table 1 describes anticipated volume percentages, induction values, and corresponding core loss for a particular motor component geometry at a frequency of 400 Hz.

TABLE 1
Exemplary Simulated Magnetic Flux Distribution at 400 Hz

| | | Core | Anticipated |
|---|---|---|---|
| Frequency | Induction | Loss (M1) | Volume |
| (Hz) | (T) | (W/kg) | (%) |
| 400 | 1.5 | 22.4 | 1 |
| 400 | 1.6 | 24.5 | 2 |
| 400 | 1.7 | 27.5 | 4 |
| 400 | 1.8 | 30.0 | 5 |
| 400 | 1.9 | 33.2 | 8 |
| 400 | 2.0 | 36.6 | 80 |

| | | |
|---|---|---|
| Measured magnetic property | 36.3 | W/kg |
| M2 of the portion of the | | |
| finished motor component | | |
| at 400 Hz, above flux | | |
| distribution | | |
| Adjusted stack loss at | 37.7 | W/kg |
| 400 Hz, 2 T (W/kg) (M3) | | |

At a frequency of 400 Hz, the induction of 1% of the volume of the geometry may be 1.5 T, the induction of 2% of the volume of the geometry may be 1.6 T, the induction of 4% of the volume of the geometry may be 1.7 T, the induction of 5% of the volume of the geometry may be 1.8 T, the induction of 8% of the volume of the geometry may be 1.9 T, and the induction of 80% of the volume of the geometry may be 2 T.

Core loss values for specific inductions are obtained by determining the measured magnetic property M1 of the loose ring set. The core loss of the 1% of volume of the geometry at an induction of 1.5 T may be 22.4 W/kg, the core loss of the 2% of volume of the geometry at an induction of 1.6 T may be 24.5 W/kg, the core loss of the 4% of volume of the geometry at an induction of 1.7 T may be 27.5 W/kg, the core loss of the 5% of volume of the geometry at an induction of 1.8 T may be 30.0 W/kg, the core loss of the 8% of volume of the geometry at an induction of 1.9 T may be 33.2 W/kg, and the core loss of 80% of the volume of the geometry at an induction of 2 T may be 36.6 W/kg.

The core loss S1 of the simulated finished motor component may be calculated by taking the weighted average of the calculated core losses. In this example, the core loss is calculated using the following equation:

$$Core Loss = ( 22.4 \frac{W}{k g} ) ( 0.01 ) + ( 24.5 \frac{W}{k g} ) ( 0.02 ) + ( 27.5 \frac{W}{k g} ) ( 0.04 ) + ( 30. \frac{W}{k g} ) ( 0.05 ) + ( 33.2 \frac{W}{k g} ) ( 0.08 ) + ( 36.6 \frac{W}{k g} ) ( 0.80 ) = 35.25 \frac{W}{k g}$$

The magnetic property correction factor S1/M1 at 400 Hz, 2 T is 0.963, calculated by dividing the core loss S1 (35.25 W/kg) by the core loss M1 at 2 T (36.6 W/kg), shown in Table 1. The measured magnetic property M2 of the portion of the finished motor component is 36.3 W/kg. The calculated finished motor component core loss M3 for the values in Table 1 is 37.7 W/kg, calculated by dividing the measured magnetic property M2 (36.3 W/kg) by the magnetic property correction factor (0.963).

While the principles of the disclosed subject matter have been described herein, it is to be understood by those skilled in the art that this description is made only by way of example and not as a limitation as to the scope of the disclosed subject matter. Other embodiments are contemplated within the scope of the present disclosed subject matter in addition to the exemplary embodiments shown and described herein. Modifications and substitutions by one of ordinary skill in the art are considered to be within the scope of the present disclosed subject matter, which is not to be limited except by the following claims.

What is claimed is:

1. A method of determining a magnetic property of a finished motor component comprising a stack including a plurality of mechanically coupled component layers, the method comprising:
measuring a loose ring set of at least one loose ring with a uniform magnetic flux distribution to determine a measured magnetic property M1 of the loose ring set, each loose ring having a same thickness and material parameters as at least one component layer of the stack of the finished motor component;
fabricating the finished motor component, wherein the finished motor component comprises the stack;
measuring the finished motor component to determine a measured magnetic property M2 of a portion of the finished motor component;
performing a finite element analysis simulation to determine a simulated magnetic flux distribution of a geometry of the finished motor component;
calculating a simulated magnetic property S1 of a plurality of component layers corresponding to the mechanically coupled component layers of the finished motor component using the simulated magnetic flux distribution, wherein the simulated magnetic property S1 is a function of the measured magnetic property M1 of the loose ring set;
calculating a magnetic property correction factor based on a ratio of (i) the simulated magnetic property S1 of the plurality of component layers to (ii) the measured magnetic property M1 of the loose ring set; and
determining a magnetic property M3 of the finished motor component by dividing the measured magnetic property M2 of the portion of the finished motor component by the magnetic property correction factor.

2. The method of claim 1, wherein the finished motor component comprises a stator or a rotor.

3. The method of claim 1, wherein the magnetic property M1, M2, M3 is at least one of magnetic flux density, magnetic field strength, and core loss.

4. The method of claim 3, wherein the magnetic property M3 is determined using at least one of (i) a plurality of flux densities or (ii) a plurality of frequencies.

5. The method of claim 3, wherein the magnetic property M3 comprises core loss, and determining the measured magnetic property of the loose rings comprises calculating the core loss.

6. The method of claim 1, wherein the portion of the finished motor component is a back iron portion.

7. The method of claim 6, wherein the portion of the finished motor component is a tooth extending radially from the back iron portion.

8. The method of claim 1, wherein the portion of the finished motor component is a portion of a cylindrical body of the finished motor component.
